(19) United States
(12) Patent Application Publication
(10) Pub. No.: US 2002/0137353 A1
(43) Pub. Date: Sep. 26, 2002

(54) Method and device for delacquering an area on a mask substrate

(76) Inventors: Josef Mathuni, Munchen (DE); Gunther Ruhl, Dorfen (DE)

Correspondence Address: LERNER AND GREENBERG, P.A., Post Office Box 2480, Hollywood, FL, 33022-2480, US

(21) Appl. No.: 10/106,134

(22) Filed: Mar. 26, 2002

(30) Foreign Application Priority Data
Mar. 26, 2001 (DE) 101 14 861.5

(51) Int. Cl. H01L 21/302; H01L 21/461

(52) U.S. Cl. 438/708

(57) ABSTRACT

A method and a device are proposed for delacquering a mask substrate, in the case of which, in particular, the edge zone of a photomask is delacquered. During the mask production, the mask substrate is coated over its entire surface with a layer of photoresist by the production process. The side edges can also be coated with resist in this case. During later handling of the mask substrates, very small resist particles can come loose, for example owing to handling tools such as mask pincers, and lead through deposits on the emulsion side to defects in the layout of the mask substrates such that the photomask can then no longer be used in practice. This fault can be avoided by delacquering the edge zone with the aid of a chemical etching reaction, in particular by using an ozone-containing gas.

### BACKGROUND OF THE INVENTION

### Field of the Invention

The invention relates to a method and a device for delacquering an area on a mask substrate, in particular an edge zone. Before the delacquering occurs, the mask substrate has a photoresist applied to one emulsion side and/or at least one side edge of the mask substrate.

Integrated circuits on semiconductor substrates are normally produced using planar technology. This includes a sequence of individual processes that act in each case over the whole of the surface of the wafer and lead specifically to local variations of the semiconductor material via suitable masking layers. In planar technology, the local processing of the semiconductor material is usually performed with the aid of lithographic methods in which photomasks are used in order to image structures to be generated on a thin radiation-sensitive film, usually an organic layer on the semiconductor substrate, and then to transfer them into the semiconductor layers with the aid of special etching methods.

The photomasks generally contain the pattern of a design level of the electric circuit, to be generated in the semiconductor material, as a chromium layer on a transparent support. The starting material for producing a photomask is in this case a mask substrate that is usually formed of glass or silica, and the whole surface of which is covered with chromium as a light-absorbing layer. The chromium layer is coated over its whole surface with a photoresist or an electron-beam resist as a radiation-sensitive film. Depending on the desired exposure method, the corresponding structures of the design level are then imaged in the resist layer in an appropriate size ratio, for example 1:1 or else 10:1. Electron-beam methods or optical methods by a pattern generator are available for this purpose. In accordance with the method, during application of the resist layer on the chromium layer of the mask substrate the outer edge zones and the side edges are also coated with resist. However, during handling of the mask substrate it is precisely the edge region that is subjected to relatively strong mechanical loading with handling tools such as mask pincers, automatic handlers or storage cassettes. Since the resist layer is not suitable for this type of loading, resist particles can come loose in this case and lead to defects through deposition on the emulsion side of the photomask, since each microchip copied with the aid of the photomask would then have the same fault. This failure mechanism is adequately known. No satisfactory solution has been found to date for delacquering the edge zones of a photomask. The current phototechnical etching methods from wafer processing such as solvent delacquering are not suitable for delacquering edge zones, because of the geometries and the dimensions of the mask substrates, since they cannot be carried out on photomasks.

### SUMMARY OF THE INVENTION

It is accordingly an object of the invention to provide a method and a device for delacquering an area on a mask substrate which overcomes the above-mentioned disadvantages of the prior art methods and devices of this general type, in which it is possible to remove resist areas on a mask substrate in a simple and reliable way.

With the foregoing and other objects in view there is provided, in accordance with the invention, a method for delacquering an area on a mask substrate. The mask substrate has a photoresist applied to an emulsion side and/or at least one side edge of the mask substrate. The method includes removing the photoresist in the area to be delacquered with an aid of a chemical etching reaction.

In accordance with the invention, the photoresist is removed with the aid of a chemical etching reaction. Removing resist locally and without residues can be carried out on a photomask substrate in a simple way by the technique according to the invention, since the chemical etching reaction can easily be restricted locally and, moreover, ensures reliable removal of the resist. The mask quality and also the output can therefore be raised advantageously by the invention.

It is preferred to make use for the chemical etching reaction of an ozone-containing gas that reacts with the photoresist on the mask substrate and converts the latter into volatile etching products such as carbon. The volatile etching products can then easily be extracted with the excess ozone, thus reliably avoiding the risk of deposits on the emulsion side of the photoresist.

It also proves to be particularly advantageous, in particular, to heat the area to be delacquered locally. The heating substantially raises the rate of reaction such that the delacquering takes place in a very much shorter time than if the operation were carried out at room temperature. It is particularly favorable in this case that because of the large temperature differences the delacquering takes place essentially only at the locally heated focal spot, whereas adjacent areas that are substantially cooler because of the poor thermal conduction of the mask substrate remain virtually unchanged. This results in a very effective selective delacquering that can advantageously be applied even to sites that are hard to reach such as the side edges. A further advantage also resides in the fact that the gas feed need not be so accurately dosed, and can be performed with success, since the resist is removed essentially only at the heated focal spot.

The area to be delacquered is advantageously heated with the aid of optical radiation specifically to as high a temperature as possible, preferably at least 150° C. Such optical heating can easily be controlled, for example via a current controller, such that it is also possible thereby to set a desired temperature for the focal spot.

A laser can advantageously be used as a suitable light source. Modern lasers supply sufficient thermal energy for heating the focal spot, and can be focused very accurately, such that advantageously only the desired area is heated. Scattered light that could damage other areas is prevented by simple methods.

A somewhat more cost-effective solution is seen in lamp heating, for example in an incandescent lamp. Incandescent lamps generate visible light only to a slight fraction. The predominant energy fraction consists of thermal radiation in the nonvisible region. The radiation can advantageously be focused onto the area to be delacquered with the aid of simple optical lenses.

A favorable solution is also to be seen in selecting the wavelength of the light such that the scattered light produced causes no damage to the remaining resist surfaces of the mask substrate.

In order to avoid scattered light, it is proposed to position the gas nozzle and the optical heater jointly in the immediate vicinity of the area to be delacquered.

It is also considered as a particularly favorable solution that the light beam is guided inside the nozzle. Using this combination, it is possible with the aid of simple mechanical devices for the nozzle and the optical radiation to be guided jointly, that is to say relative to the moving table over the area to be delacquered.

An alternatively advantageous solution results when the optical radiation is guided outside the nozzle. This prevents the ozone-containing gas from heating up prematurely and then possibly also heating undesired surfaces at which the photoresist could be stripped away, at least partially. In the case of this configuration, a further advantage also consists in that the ozone-containing gas can be blown in with an excess, since it cannot cause any damage on the contiguous cold resist areas.

With the foregoing and other objects in view there is also provided, in accordance with the invention, a device for delacquering an area on a mask substrate. The mask substrate has a photoresist applied on an emulsion side and/or at least one edge of the mask substrate. The device contains a table, a holder disposed on the table, the holder fixing the mask substrate on the table, and a feed for providing an etching gas. The feed has an exit aperture that is aligned with the area, to be delacquered, of the mask substrate. The etching gas assists in removing the photoresist in the area to be delacquered with an aid of a chemical etching reaction. Preferably, the feed is in the form of a nozzle.

The device with the moving table and the nozzle disposed there above has the advantage of simple and reliable handling. For example, commercially available moving tables can be converted with low outlay for the purpose of delacquering mask substrates. The nozzle can be disposed in a fixed fashion in this case, such that the relative displacement can be performed by controlling the moving table.

It is also advantageous to align the optical heater only with the area to be delacquered, such that it is possible for the edge zones of the mask substrate, for example, to be delacquered very specifically.

The delacquering of the mask substrate can be performed particularly simply by placing and fixing the mask substrate on a moving table that can preferably be moved along the three axes x, y and z. In the case of the configuration, the nozzle and the optical heater are then disposed permanently above the area to be delacquered, and the moving table is preferably moved in the desired directions with the aid of a software program. Automated delacquering of many mask substrate wafers can easily be carried out in this way.

In accordance with an added feature of the invention, an optical system is disposed downstream of the light source and the light source is an incandescent lamp whose radiation is restricted by the optical system.

Other features which are considered as characteristic for the invention are set forth in the appended claims.

Although the invention is illustrated and described herein as embodied in a method and a device for delacquering an area on a mask substrate, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, perspective view with a partial sectional view of a first exemplary embodiment of a nozzle configuration, in the case of which optical radiation is guided inside the nozzle according to the invention; and

FIG. 2 is a sectional view of a second exemplary embodiment of the invention, in the case of which the optical radiation is carried outside the nozzle.

### DESCRIPTION OF THE PREFERRED EMBODIMENTS

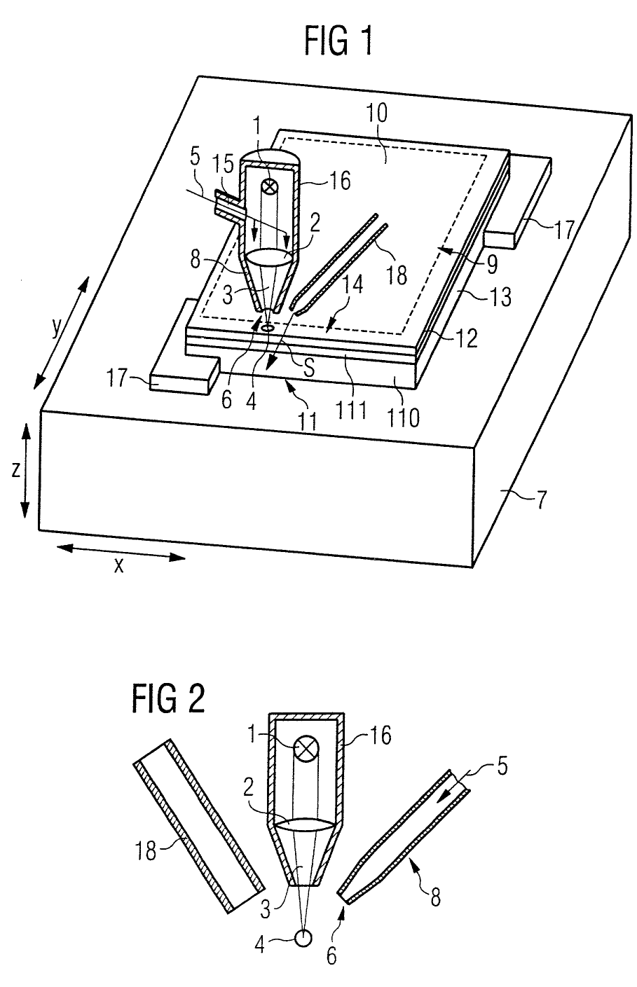

Referring now to the figures of the drawing in detail and first, particularly, to FIG. 1 thereof, there is shown a first exemplary embodiment of the invention in a schematic illustration. Provided on a moving table 7 are holders 17 by which a mask substrate 11, what is termed a blank, for a photomask 10 to be manufactured can be fixed on the moving table 7. The mask substrate 11 preferably contains a glass or silica plate 110 coated over its whole surface with a chromium layer 111 made from a light-absorbing material. The chromium layer 111 is, in turn, coated over its whole outside with a photoresist layer 12 on an emulsion side 9. The desired structures of a design level for an integrated circuit on a semiconductor component can then be imaged later onto the resist layer 12 with the appropriate proportions depending on the exposure method. Electron beam methods and/or optical methods by a pattern generator are then available for this purpose. After development of the photoresist, the exposed structures are then etched into the chromium layer 111 in order to produce the pattern of the design level in the chromium layer.

The photoresist layer 12 is applied to the mask substrate 11 virtually over the whole mask substrate, in particular also to the side edges, depending on the production of the coating. For reasons of quality and reliability, the further handling of the mask substrate 11 is particularly disturbed by the photoresist in the edge zone delimited by dashes and at side edges 13 of the mask substrate 11.

The moving table 7 is preferably mounted movably in the directions x, y and z, such that its position can be displaced in steps in a desired direction. The displacement is preferably performed with the aid of a computer that can be controlled by an appropriate software program. An automatic station for delacquering the mask substrates 11 can then easily be constructed with the aid of this device. For reasons of clarity, the mechanical and electrical parts of the controller are, however, omitted in FIG. 1. Such moving tables are known per se in semiconductor fabrication and need not therefore be described in more detail.

The holder 17 can be provided in different configurations. Instead of stop angles drawn at two opposite corners, it is also possible to provide optical marks or the like for positioning the mask substrate 11 exactly. This appears sensible, in particular, in the case of automatic handling of the mask substrates 11 with gripper arms or the like. The mask substrate 11 is fixed by being jammed in or else, for example, by an underpressure between the bearing surface of the moving table 7 and the underside of the mask substrate 11. However, the fixing must be so firm that the mask substrate 11 cannot be displaced by blowing on an etching gas, an ozone containing gas 5 in the embodiment. On the other hand, the holder 17 or the fixing device is not permitted either to damage the mask substrate 11 or to cover areas 14 to be delacquered, in particular the edge zones and the side edges 13.

A housing 16 is disposed above the mask substrate 11 at the area 14 that is to be delacquered, at a site of the area drawn with the dashes. The housing 16 is, for example, of a cylindrical configuration and sealed at its circumference and its upper end in a light-tight and gas-tight fashion. Disposed at its lower end is a nozzle 8 with an exit aperture 6 via which the ozone-containing gas 5 is blown out. The nozzle 8 is aligned in this case with the area 14 to be delacquered.

The ozone-containing gas 5 is fed via a gas feed 15 disposed laterally on the housing 16. It flows through the housing 16 and exits at the exit aperture 6. Also disposed in the housing 16 is an optical heater 1 whose optical radiation, which acts substantially as thermal radiation, is focused via an optical system 2 and likewise exits at the exit aperture 6.

A simple incandescent lamp producing white light can be used as the optical heater 1. An alternative refinement of the invention provides using a laser as the optical heater 1. It is to be ensured that as far as possible no scattered light is produced when focusing the optical radiation. This is achieved, for example, by a suitable choice of the spacing between the emulsion side 9 of the mask substrate 11 and the exit aperture 6 of the nozzle 8. Moreover, the wavelength of the light source used as the optical heater 1 can be selected such that scattered light occurring has no damaging effect on the photoresist layer 12 in the region not to be delacquered.

Since the optical heater 1 is intended essentially to heat up the photoresist layer 12 on the emulsion side 9 of the mask substrate 11 only at a focal spot 4, the wavelength of the light is itself of no importance for the removal process.

The optical heater 1 serves the purpose of heating up the photoresist layer 12 at the areas 14 to be delacquered to a temperature at which there is a measurable chemical reaction between the ozone-containing gas 5 and the resist layer. The ozone-containing gas reacts with the photoresist layer 12 to produce volatile etching products such as carbon dioxide. However, an appreciable chemical reaction is not achieved until temperatures above approximately 150° C. The optical heater 1 heats up the areas 14 to be delacquered locally above the temperature threshold, in order to be able to achieve quick and effective delacquering. Locally heating up the area 14 to be delacquered by appropriate control of the focal spot 4 is also ensured by virtue of the fact that the silica glass plate 110 has poor thermal conduction, and so the photoresist layer 12 essentially heats up only at the focal spot 4 itself.

Another advantage of such temperature control of the etching process is that it is possible for excess ozone-containing gas 5 to flow out without regard to the remaining resist layer, since no appreciable etching reactions can take place here owing to the low temperature in the photoresist layer 12. The volatile etching products and the excess ozone-containing gas are extracted with the aid of an extraction device 18 so that they cannot be deposited on the surrounding photoresist areas of the mask substrate 11.

Other etching gases can also, however, be used as an alternative to the use of an ozone-containing gas. In order then to produce a local etching reaction here, either use is also made of a gas that ensures an appreciable etching rate only at a certain temperature threshold, or it is reliably ensured via the nozzle 8 or another gas outflow device that the etching gas flows out only onto the desired area to be delacquered.

The housing 16 with the nozzle 8 and the optical heater 1 are disposed displaceably relative to the mask substrate 11 and the moving table 7, as already described above. However, it can also be provided that the housing 16 can, for example, be pivoted into the illustrated S direction during the delacquering operation. This has the advantage that it is possible thereby to control the width of the area 14 to be delacquered in a simple way.

The mode of operation of the configuration is explained in more detail below. The mask substrate 11 to be delacquered is fixed on the moving table 7. In order to delacquer the edge zone of the mask substrate 11 drawn with dashes, the nozzle 8 is positioned above the edge zone in the immediate vicinity and as close as possible. The ozone-containing gas 5, the optical heater 1 and the extraction device 18 are then switched on, thus starting the delacquering operation at the focal spot 4. The temperature of the focal spot 4 is controlled via the lamp current such that an optimum delacquering result is achieved. For the purpose of delacquering, the moving table 7 now displaces the focal spot 4 along the area 14 to be delacquered until the area 14 has been completely delacquered.

In order to control the width of the delacquering zone, the nozzle 8 can additionally be pivoted into the S direction.

Alternatively, it can also be provided to pivot only the nozzle 8 above the area 14 to be delacquered, while the moving table 7 is then fixed.

FIG. 2 shows a second exemplary embodiment of the invention. The moving table 7 with the holders 17 and the holding of the mask substrate 11 resembles the illustration in FIG. 1. In contrast, the difference is the configuration of the nozzle 8 for the ozone-containing gas 5 and the optical heater 1. The nozzle 8 is disposed separately and in the vicinity of the housing 16. The optical heater 1 again produces the focal spot 4 on the area 14 to be delacquered. The nozzle 8 with the exit aperture 6 for the ozone-containing gas 5 is directed onto the focal spot 4.

The functional cycle corresponds to that as described in FIG. 1.

As an alternative to the two exemplary embodiments illustrated, instead of an optical heater 1 it is also possible to use a different type of heater that is disposed, for example on the moving table 7 for the purpose of local heating of the resist layer. It is also possible in this case for the photoresist layer 12 on the mask substrate 11 to be heated up substantially over its whole surface, and instead for the ozone-containing gas that ensures the etching reaction to flow locally onto the areas to be delacquered.

The features of the invention disclosed in the above description, the drawings and the claims can, moreover, be significant both individually and in any desired combination for implementing the invention in its various refinements.

We claim:

1. A method for delacquering an area on a mask substrate, the mask substrate having a photoresist applied to at least one of an emulsion side and at least one side edge of the mask substrate, which comprises the steps of:
removing the photoresist in the area to be delacquered with an aid of a chemical etching reaction.

2. The method according to claim 1, which comprises converting the photoresist into volatile etching products in the area to be delacquered with the aid of the chemical etching reaction.

3. The method according to claim 2, which comprises extracting the volatile etching products of the photoresist.

4. The method according to claim 1, which comprises using an ozone-containing gas for creating the chemical etching reaction with the photoresist in the area to be delacquered.

5. The method according to claim 4, which comprises directing substantially only the ozone-containing gas onto the area to be delacquered.

6. The method according to claim 4, which comprises heating locally the area to be delacquered to initiate the chemical etching reaction between the photoresist and the ozone-containing gas.

7. The method according to claim 6, which comprises heating the area to be delacquered with an aid of optical radiation.

8. The method according to claim 7, which comprises heating the area to be delacquered with an aid of a laser.

9. The method according to claim 7, which comprises heating the area to be delacquered with an aid of an incandescent lamp whose radiation is restricted to the area to be delacquered by an optical system.

10. The method according to claim 7, which comprises selecting a wavelength of the optical radiation so as to avoid exposing the photoresist to scattered light.

11. The method according to claim 1, which comprises using silica glass as a support plate for the mask substrate.

12. The method according to claim 4, which comprises heating locally the area to be delacquered to at least 150° C.

13. The method according to claim 1, which comprises removing the photoresist from an edge region of the mask substrate.

14. A device for delacquering an area on a mask substrate, the mask substrate having a photoresist applied on at least one of an emulsion side and at least one edge of the mask substrate, the device comprising:
a table;
a holder disposed on said table, said holder fixing the mask substrate on said table; and
a feed for providing an etching gas, said feed having an exit aperture formed therein being aligned with the area, to be delacquered, of the mask substrate, the etching gas assists in removing the photoresist in the area to be delacquered with an aid of a chemical etching reaction.

15. The device according to claim 14, wherein said feed for the etching gas is a nozzle.

16. The device according to claim 15, further comprising a heater to heat the area, to be delacquered, of the mask substrate locally.

17. The device according to claim 16, wherein said heater is a light source whose radiation is aligned with the area to be delacquered.

18. The device according to claim 17, wherein said light source is a laser.

19. The device according to claim 17, further comprising an optical system disposed downstream of said light source, and said light source is an incandescent lamp whose radiation is restricted by said optical system.

20. The device according to claim 17, wherein said light source operates with a wavelength that avoids exposing the photoresist to scattered light.

21. The device according to claim 17, wherein said nozzle and said light source are positioned in an immediate vicinity of the area to be delacquered.

22. The device according to claim 21, wherein optical radiation is guided inside said nozzle.

23. The device according to claim 14, wherein said table is a shift unit to execute relative movement between said holder for fixing the mask substrate and said feed for guiding the etching gas.

24. The device according to claim 23, wherein said shift unit is a moving table that can be moved in steps in x, y and z directions, and on which said holder for fixing the mask substrate is disposed.

25. The device according to claim 14, further comprising an extraction device to remove at least one of etching products and unused etching gas.

26. The device according to claim 14, wherein said feed is configured for providing an etching gas containing ozone.

27. The device according to claim 16, wherein said heater heats the area, to be delacquered, of the mask substrate to at least 150° C.
